(19) United States
(12) Patent Application Publication
(10) Pub. No.: US 2006/0103272 A1
(43) Pub. Date: May 18, 2006

(54) Mounting assembly for computer cover

(75) Inventors: Yun-Lung Chen, Tu-Cheng (TW); Lin Ding, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/150,993

(22) Filed: Jun. 13, 2005

(30) Foreign Application Priority Data
Nov. 15, 2004 (CN) 200420095589.X

(51) Int. Cl. H05K 5/00

(52) U.S. Cl. 312/223.2

(57) ABSTRACT

A mounting assembly for computer cover includes a chassis (50) with a rearwall (54), a cover (10) forms a pressing tab (16) at a distal end thereof, the mounting assembly for computer cover further includes a positioning member (20) mounted slidably on the rearwall (54) of the chassis (50), and the positioning member (20) has a first pressed portion (22). Pushing flatly and forward the cover (10) can engage the first pressed portion (22) with the pressing tab (16). Thus the cover (10) is mounted to the chassis (50). When pushing the positioning member (20) downwardly can disengage the first pressed portion (22) with the pressing tab (16). Thus the cover (10) is easily demounted from the chassis (50).

### BACKGROUND OF THE INVENTION

1. Field of the Invention

The present invention relates to a mounting assembly for a computer cover, and more particularly to a mounting assembly for a computer cover for demounting or mounting computer cover conveniently.

2. Background of the Invention

With the popularization of computer, it is required that a computer cover should be demounted and mounted conveniently for checking malfunction of hardware and repairing interior members of a computer. A typical mounting assembly usually utilizes a plurality of screws, directly attaching a computer cover to a computer chassis. Thereby, screwdrivers or other detaching tools are necessary for installation or removal of the computer cover, which causes inconvenience and time waste.

Conventionally, a mounting assembly for a computer cover is disclosed in Taiwan patent application No. 089,222,643. The mounting assembly for a computer cover comprises a chassis, a cover and two symmetrical plates. The chassis includes a bottom panel, a top panel, a front panel and a rear panel. A flange is vertically formed at an edge of each panel. Each adjacent flange symmetrically forms a first side frame and a second side frame. A supporting panel is mounted to the inner side of the first side frame. The two side edges of the cover are both bent to form a rim, defining a plurality of hooks for clipping with corresponding holes of the chassis respectively for assembling the cover, the first side frame and the second side frame. However, The conditional mounting assembly utilizes a plurality of screws to secure the cover, and screwdrivers or other detaching tools are required during the course of demounting or mounting the cover. Therefore, it is complicated and inconvenient to demount and mount.

Another typical mounting assembly is disclosed in Taiwan patent application No. 088,222,604. The mounting assembly is arranged at an end of a chassis for demounting or mounting a cover. A rearwall is inward bent to form a supporting plate with a hole defined therein. The cover is inward bent to form a locking tab with a locking opening defined and a second abutting portion. The mounting assembly comprises a lever having a locking portion and a first abutting portion, and a resilient device locating between the supporting plate and the lever. The locking opening of the locking tab engages the locking portion. Pulling the lever can release the locking portion from the locking opening, and then the first abutting portion of the lever pushes the second abutting portion of the lever. Although the mounting assembly need not use screwdrivers, the operation of above described mounting assembly is unduly complicated.

What is needed is to provide a mounting assembly with a simplified configuration, and convenient to demount or mount a cover from/to a chassis.

### SUMMARY

A mounting assembly in accordance with a preferred embodiment of the present invention comprises a chassis with a rearwall and a cover. The rearwall is formed to have a retaining tab and two L-shaped locating tabs, and the cover forms a pressing tab at a distal end thereof. The mounting assembly further comprises a positioning member. The positioning member which is enclosed by the two locating tabs and retaining tab can slide up and down at a rear end of the chassis, and the positioning member has a first pressed portion at a top end thereof. Pushing flatly and forward the cover can engage the first pressed portion with the pressing tab. The cover is therefore securely attached to the chassis. Moving the positioning member downwardly can disengage the first pressed portion with the pressing tab. The cover is therefore easily demounted from the chassis.

Other advantages and novel features of the present invention will be drawn from the following detailed description of preferred embodiment of the present invention with the attached drawings, in which:

### BRIEF DESCRIPTION OF THE DRAWINGS

FIG. 1 is an exploded, isometric view of a mounting assembly in accordance with a first preferred embodiment of the present invention comprising a cover, a positioning member, a pressing member, a spring and a chassis;

FIG. 2 is an enlarged, isometric view of part II in FIG. 1;

FIG. 3 is an enlarged, isometric view of the cover of FIG. 1, but viewed from another aspect;

FIG. 4 is an enlarged, isometric view of the positioning member of FIG. 1, but viewed from another aspect;

FIG. 5 is an assembled isometric view of FIG. 2, without mounting the cover;

FIG. 6 is an assembled isometric view of the mounting assembly, with the cover mounted;

FIG. 7 is an enlarged, isometric view of part II in FIG. 1 in accordance with a second preferred embodiment of the present invention;

FIG. 8 is an enlarged, isometric view of the positioning member of FIG. 7, but viewed from another aspect; and

FIG. 9 is an assembled isometric view of the mounting assembly of FIG. 7.

### DETAILED DESCRIPTION OF THE INVENTION

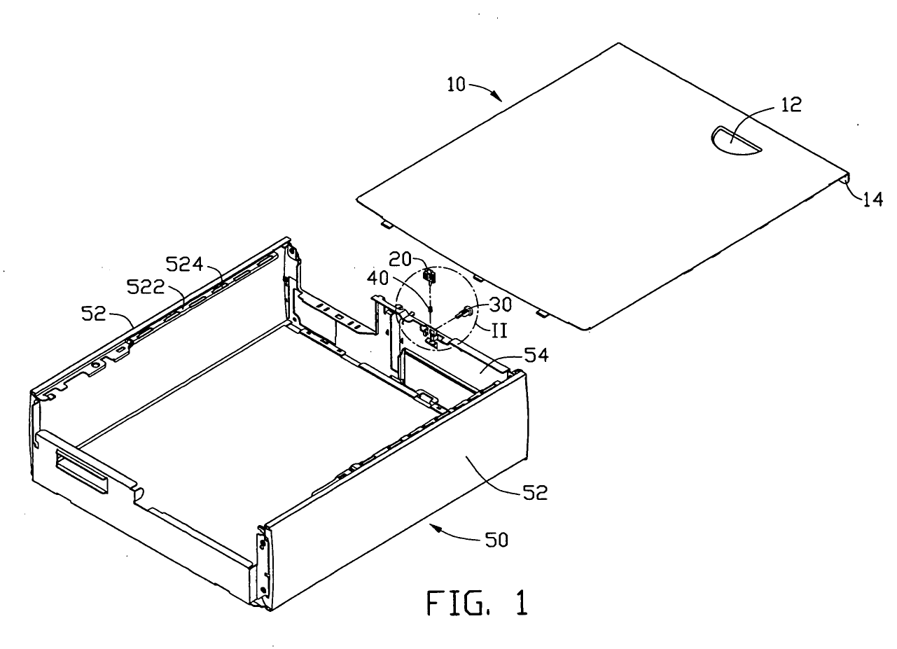

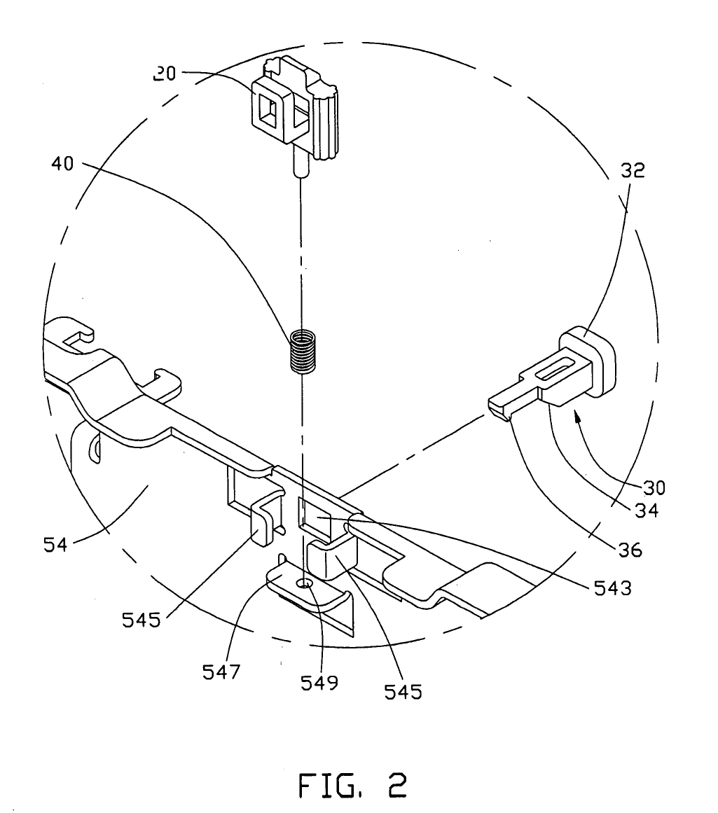

Referring to FIGS. 1 and 2, a mounting assembly in accordance with a first preferred embodiment of the present invention comprises a cover 10, a positioning member 20, a pressing member 30, a spring 40 and a chassis 50. In the first preferred embodiment of the present invention, the spring 40 can be other elastic components.

The chassis 50 comprises two opposite sidewalls 52 and a rearwall 54 therebetween. The upper edge of each sidewall 52 is bent perpendicularly inward to form a flange 522, and a plurality of slots 524 are defined thereon. The rearwall 54 of the chassis 50 defines an rectangular opening 543 therein. Two L-shaped locating tabs 545 are protruded inward at two sides of the rectangular opening 543. A retaining tab 547 protrudes inward under the rectangular opening 543. A fixing hole 549 is defined in the retaining tab 547. The pressing member 30 is approximately post-shaped, which has a pressing portion 32 at one end, a pushing portion 34 with a slant at a middle portion thereof, and a downward hook 36 at the other end.

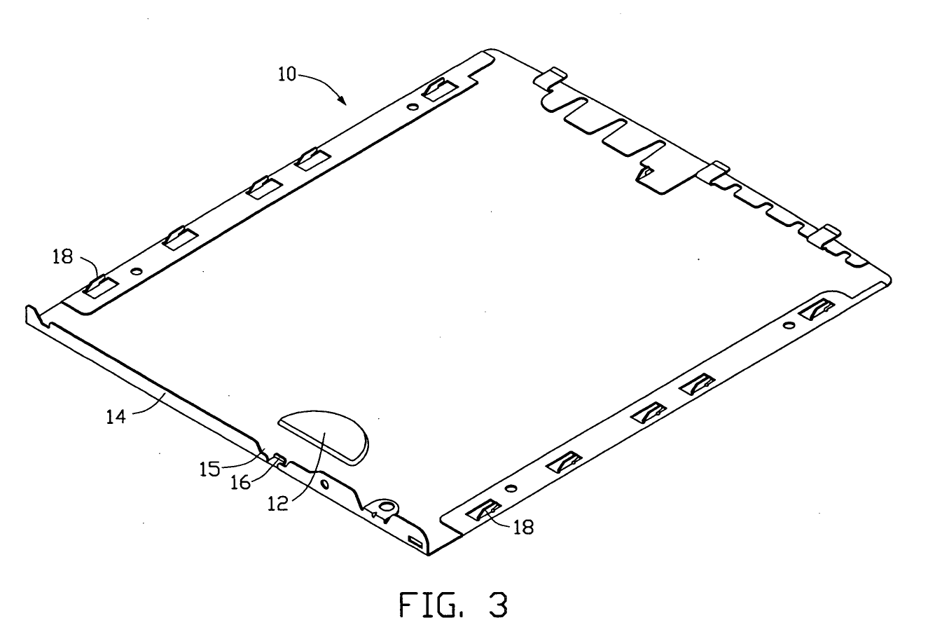

Referring also to FIG. 3, the rear portion of the cover 10 is formed to have a recess 12. A flange 14 is perpendicularly formed at an edge of the cover 10, with a cutout 15 defined therein. An L-shaped pressing tab 16 is formed inward adjacent to the cutout 15. The cover 10 forms a plurality of hooks 18 at left and right edges thereof.

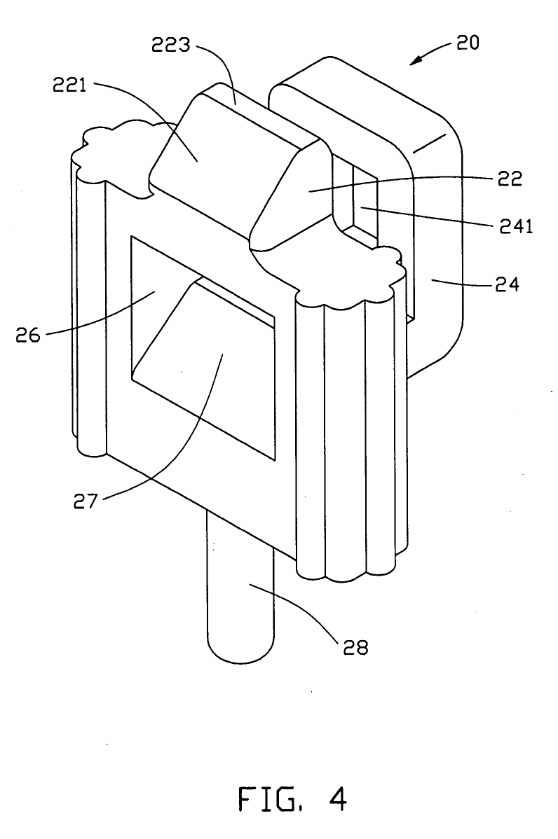

Referring to FIG. 4, a wedge-shaped first pressed portion 22 is formed on the top of the positioning member 20 which includes a guiding surface 221 and a top surface 223. An L-shaped block 24 is outward extended from the middle portion of the positioning member 20. A first rectangular through hole 241 is defined in a perpendicular portion of the block 24, and a second rectangular through hole 26 corresponding to the first rectangular through hole 241 is defined in a middle portion of the positioning member 20. A second pressed portion 27 with a slant is formed below the second rectangular through hole 26. A supporting pillar 28 is formed at a bottom of the positioning member 20.

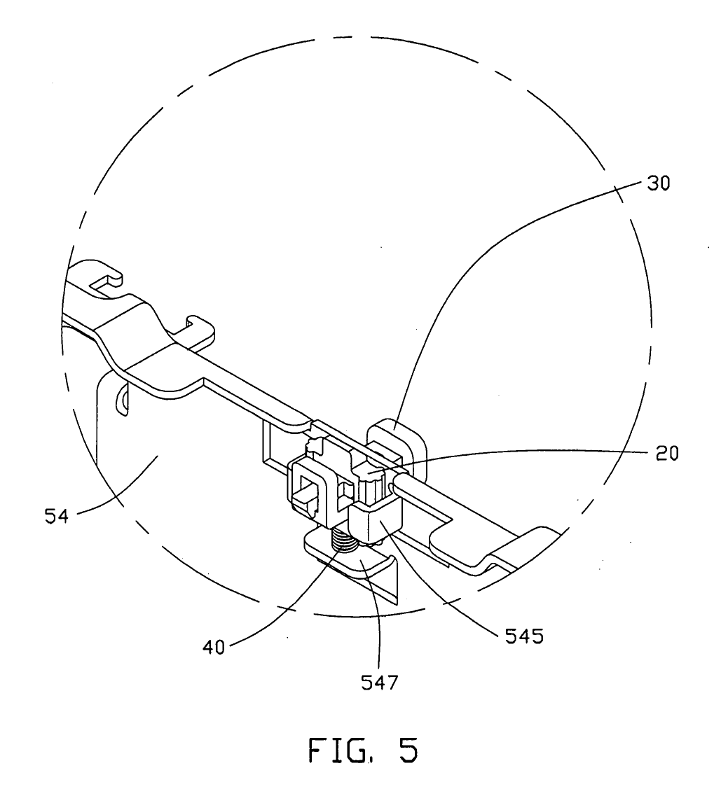

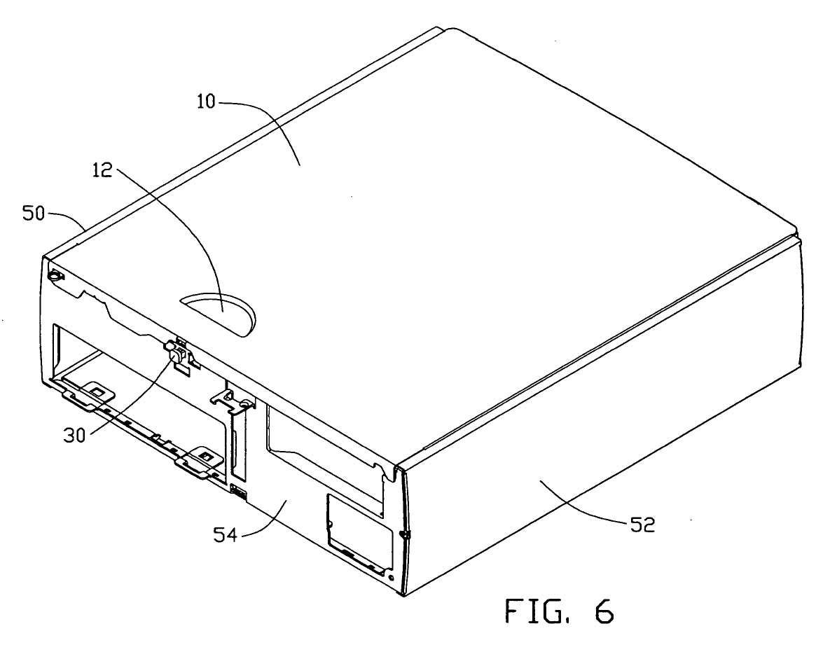

Referring also to FIGS. 5 and 6, before mounting the cover 10 to the chassis 50, the positioning member 20 has been enclosed by the two locating tabs 545 and the retaining tab 547, so that the positioning member 20 can only be moved up and down. The supporting pillar 28 of the fixing member 20 extends through the fixing hole 549 of the retaining tab 547. The spring 40 are jacketed round the supporting pillar 28. The hook 36 of the pressing member 30 can engage with the block 24 after the hook 36 extends through the rectangular opening 543 of the rear wall 54 and the through hole 26 of the positioning member 20. The pushing portion 34 of the pressing member 30 abuts against the second pressed portion 27 of the positioning member 20.

In assembly, the plurality of hooks 18 of the cover 10 is in alignment with the plurality of through slots 524 of the flanges 522, and then the cover 10 is pushed flatly and forward. The pressing tab 16 of the cover 10 pushes the first pressed portion 22 along the guiding surface 221, thereby making the positioning member 20 move downwardly, and the spring 40 compressed. Further pushing the cover 10, the pressing tab 16 rides over the top surface 223 of the first pressed portion 22 and locates between the block 24 and the first pressed portion 22. The spring 40 rebounds and lifts the positioning member 20. The first pressed portion 22 of the positioning member 20 stops the pressing tab 16 to move backwardly. The cover 10 is then mounted to the chassis 50.

In disassembly of the cover 10, when the pressing portion 32 of the pressing member 30 is pressed by thumb, the pushing portion 34 of the pressing member 30 pushes the second pressed portion 27 of the positioning member 20 to make the positioning member 20 move downwardly and the spring 40 compressed. When the top surface 223 of the first pressed portion 22 of the positioning member 20 locates below the pressing tab 16 of the cover 10, the cover 10 is dragged backwardly with recess 12. The hooks 18 disengage from the corresponding through slots 524. Thus, the cover 10 is easily demounted from the chassis 50.

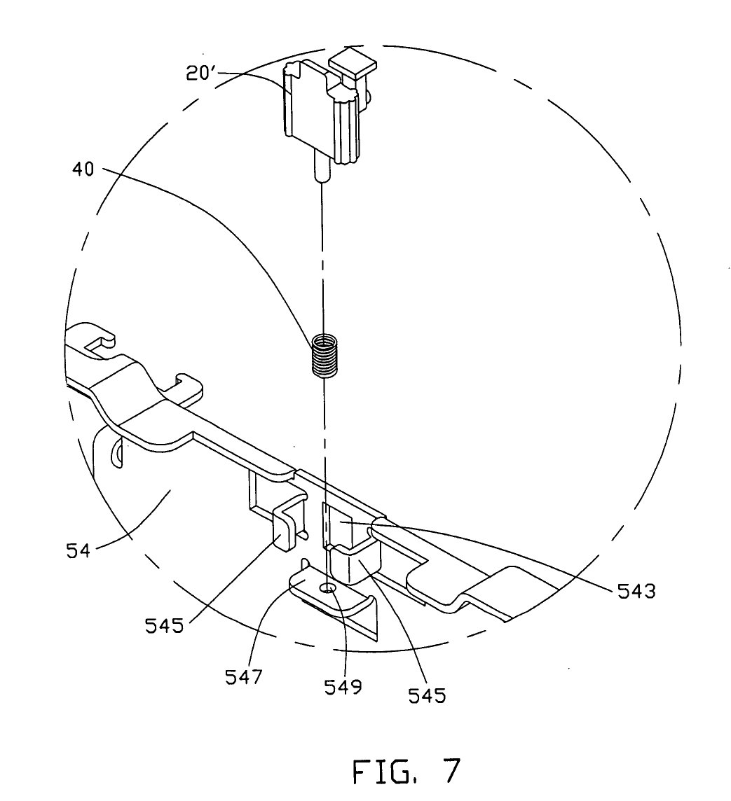

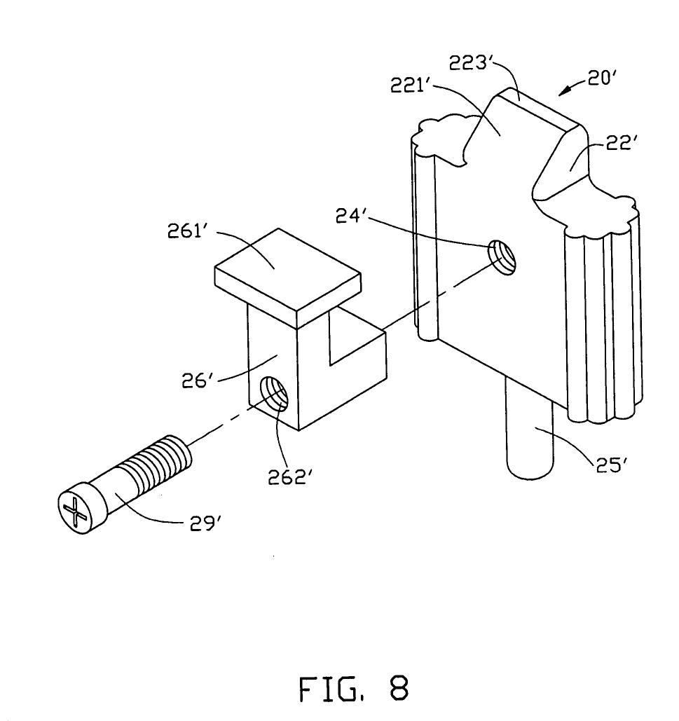

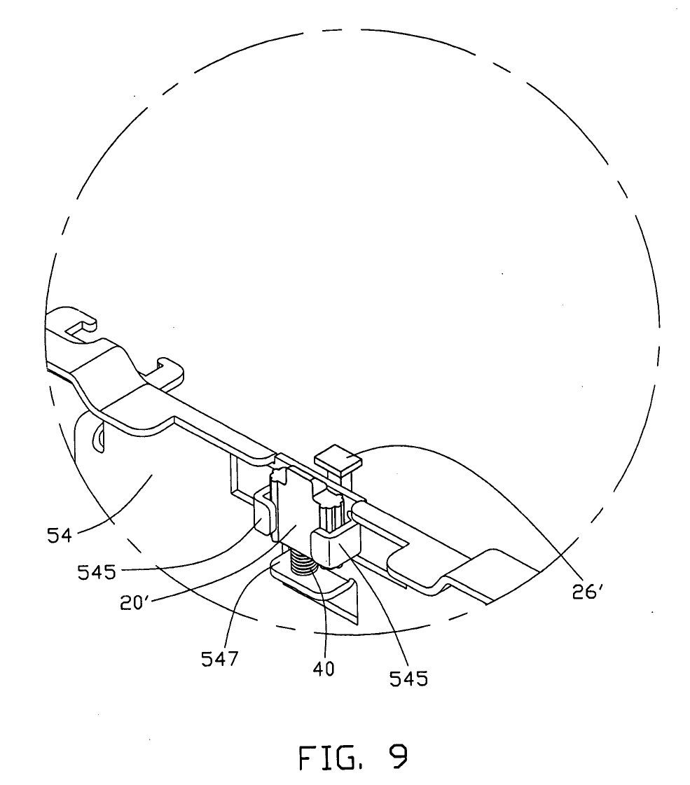

Referring to FIGS. 7, 8 and 9, a mounting assembly in accordance with a second preferred embodiment of the present invention comprises the cover 10, a positioning member 20′, a J-shaped block 26′, a screw 29′, the spring 40 and the chassis 50. In the preferred embodiment of the present invention, above-mentioned members such as the cover 10, the spring 40 and the chassis 50 is the same to the first preferred embodiment of the present invention, therefore, the label of members is not changed and follows the label of members of the first preferred embodiment of the present invention.

The positioning member 20′ is formed to have a wedge-shaped first pressed portion 22′ including a guiding surface 221′ and a top surface 223′ at the top end thereof. A screw hole 24′ is defined in the middle portion of the positioning member 20′, and a supporting pillar 25′ is also formed at the bottom portion of the positioning member 20′. The J-shaped block 26′ is formed to have a rectangular pressing portion 261′ at the top end thereof and a screw hole 262′ is defined in the bottom portion of the J-shaped block 26′.

Before mounting the cover 10 on the chassis 50, the positioning member 20′ is enclosed by the two locating tabs 545 and the retaining tab 547, so that the positioning member 20 can only be moved up and down. The J-shaped block 26′ extends through the rectangular opening 543 to be fastened on the positioning member 20 by a screw 29, which extends through the screw hole 262 of the J-shaped block 26 and the screw hole 24 of the positioning member 20. The supporting pillar 25 of the fixing member 20 extends through the fixing hole 549 of the retaining tab 547. The spring 40 is jacketed round the supporting pillar 25. Therefore, the positioning member 20 can be moved up and down due to the spring 40. When mounting the cover 10, the plurality of hooks 18 of the cover 10 is in alignment with the plurality of through slots 524 of the flanges 522. The cover 10 is then pushed flatly and forward, the pressing tab 16 of the cover 10 pushes the first pressed portion 22 along the guiding surface 221 to make the positioning member 20 move downwardly with the spring 40 compressed; Further pushing the cover 10, the pressing tab 16 rides over the top surface 223 of the first pressed portion 22. The spring 40 rebounds and lifts the positioning member 20. Thus, the first pressed portion 22 of the positioning member 20 stops the pressing tab 16 moving backwardly. The cover 10 can be thereby mounted to the chassis 50 easily.

In disassembly of the cover 10, when the pressing portion 261 of the J-shaped block 26 is pressed by thumb, the positioning member 20 moves downwardly and compresses the spring 40. When the top surface 223 of the first pressed portion 22 of the positioning member 20 locates below the pressing tab 16 of the cover 10, the recess 12 of the cover 10 is clasped and the cover 10 is dragged backwardly, therefore, the hooks 18 disengage with the corresponding through slots 524. Thus, the cover 10 is easily demounted from the chassis 50.

While the present invention has been illustrated by the description of preferred embodiment thereof, and while the preferred embodiment has been described in considerable details, it is not intended to restrict or in any way limit the scope of the appended claims to such detail. Additional advantages and modifications within the spirit and scope of the present invention will readily appear to those skilled in the art. Therefore, the present invention is not limited to the specific details and illustrative example shown and described.

We claim:

1. A mounting assembly for computer cover, comprising:
a chassis;
a cover adapted to be slidably mounted to the chassis in a first direction, a pressing tab extending from the cover;
a positioning member movably mounted on the chassis in the positioning member engagable with the pressing tab for preventing the cover from sliding on the chassis when the cover is secured, the positioning member being movable in a second direction perpendicular to the first direction; and
a pressing member for urging the positioning member to move in a second direction, thereby the positioning member disengaging from the pressing tab.

2. The mounting assembly for computer cover as described in claim 1, wherein the pressing member is a J-shaped block fastened to the positioning member.

3. The mounting assembly for computer cover as described in claim 2, wherein the J-shaped block forms a pressing portion at a top end thereof, and when the pressing portion is pressed downwardly, the positioning member moves in a second direction.

4. The mounting assembly for computer cover as described in claim 1, wherein the positioning member has a slanted pressed portion, and the pressing member has a slanted pushing portion for engaging with the pressed portion.

5. The mounting assembly for computer cover as described in claim 4, wherein the positioning member defines a through hole for the pressing member extending through.

6. The mounting assembly for computer cover as described in claim 5, wherein the pressing member has a hook at a distal end thereof, and the positioning member has an L-shaped block with a through hole defined for engaging with the hook.

7. The mounting assembly for computer cover as described in claim 1, wherein the positioning member has a spring supported.

8. The mounting assembly for computer cover as described in claim 1, wherein a pair of locating tabs and a retaining tab extend from the chassis for holding the positioning member.

9. The mounting assembly for computer cover as described in claim 1, wherein the positioning member has a first pressed portion with a slanted guiding surface formed for engaging with the pressing tab.

10. A mounting assembly for computer cover, comprising:
a chassis;
a cover adapted to be slidably mounted to the chassis;
a positioning member mounted on the chassis, the positioning member engagable with the cover for securing the cover on the chassis, the positioning member having a slanted pressed portion; and
a pressing member having a slanted pushing portion engagable with the pressed portion of the positioning member, whereby when the pressing member is pressed by the pushing portion, the positioning member is disengaged from the cover.

11. The mounting assembly for computer cover as described in claim 10, wherein the pressing member is a J-shaped block fastened to the positioning member.

12. The mounting assembly for computer cover as described in claim 11, wherein the J-shaped block forms a pressing portion at a top end thereof, and when the pressing portion is pressed, the positioning member moves downwardly.

13. The mounting assembly for computer cover as described in claim 10, wherein the positioning member defines a through hole for the pressing member extending through.

14. The mounting assembly for computer cover as claimed in the claim 13, wherein the pressing member has a hook at a distal end thereof, and the positioning member has an L-shaped block with a through hole defined for engaging with the hook.

15. The mounting assembly for computer cover as described in the claim 10, wherein the positioning member has a spring supported.

16. The mounting assembly for computer cover as described in the claim 10, wherein a pair of locating tabs and a retaining tab extend from the chassis for holding the positioning member.

17. The mounting assembly for computer cover as described in the claim 10, wherein the positioning member has a first pressed portion with a slanted guiding surface formed for engaging with the pressing tab.

18. A mounting assembly, comprising:
a chassis;
a cover adapted to be slidably mounted to the chassis in a first direction;
a positioning member movably mounted on the chassis, the positioning member engagable with the cover for securing the cover on the chassis, the positioning member being movable in a second direction perpendicular to the first direction; and
a pressing member coupled with the positioning member, the pressing member being available outside the chassis for driving the positioning member in a second direction.

19. The mounting assembly as described in the claim 18, wherein the pressing member comprises a slanted pushing portion for moving the the positioning member in the second direction.

20. The mounting assembly as described in the claim 18, wherein the positioning member has a first pressed portion with a slanted guiding surface formed for engaging with the cover.
